(19) United States
(12) Patent Application Publication
(10) Pub. No.: US 2025/0364431 A1
(43) Pub. Date: Nov. 27, 2025

(54) SEMICONDUCTOR PACKAGE AND METHOD OF MANUFACTURING THE SAME

(71) Applicant: Samsung Electronics Co., Ltd., Suwon-si (KR)

(72) Inventors: Jun Bae Kim, Suwon-si (KR); Geun Woo Kim, Suwon-si (KR)

(21) Appl. No.: 18/982,136

(22) Filed: Dec. 16, 2024

(30) Foreign Application Priority Data
May 22, 2024 (KR) 10-2024-0066465

(51) Int. Cl. H01L 23/552; H01L 23/00; H01L 23/538; H01L 25/00; H01L 25/07

(52) U.S. Cl. CPC H01L 23/552; H01L 23/538; H01L 24/48; H01L 25/074; H01L 25/50; H01L 2224/48106; H01L 2224/48227; H01L 2225/06562

(57) ABSTRACT

A semiconductor package and method of manufacturing the same are provided. The semiconductor package includes a first semiconductor chip having a first connection pad disposed on a first surface, and a second surface opposite to the first surface, a second semiconductor chip on the second surface and having a second connection pad disposed on a third surface, and a fourth surface opposite to the third surface, a connection structure on the first surface, including a redistribution layer connected to the first and second connection pads, a fifth surface facing the first surface, a sixth surface opposite to the fifth surface, and a grounding pad, a first connecting wire connecting the first connection pad and the redistribution layer, a second connecting wire connecting the second connection pad and the redistribution layer, a shielding plate on the fourth surface, and a shielding wire connecting the shielding plate and the grounding pad.

### CROSS-REFERENCE TO RELATED APPLICATION

The present application claims priority from Korean Patent Application No. 10-2024-0066465, filed on May 22, 2024, in the Korean Intellectual Property Office, and all the benefits accruing therefrom under 35 U.S.C. § 119, the disclosure of which is herein incorporated by reference in its entirety.

### BACKGROUND

The present disclosure relates to a semiconductor package and a method of manufacturing the same.

As electronic devices become smaller and more high-performance, the distance between their components decreases, and the operating speed significantly increases. This has raised issues of device malfunction due to electromagnetic interference (EMI) between the components. Consequently, there is a growing interest in EMI shielding technology. In the case of smartphones, EMI shielding technology was initially applied only to certain chips, such as early communication chips. However, recently, the application of EMI shielding technology has expanded to include application processors (APs) and radio frequency (RF) chips.

EMI shielding technology primarily uses metal can structures or deposition methods such as sputtering. When EMI shielding is achieved through deposition methods such as sputtering, additional sputtering processes are needed after manufacturing semiconductor chips. Accordingly, there is an increasing need for EMI shielding structures that can reduce manufacturing costs.

### SUMMARY

Aspects of the present disclosure provide a semiconductor package having an effective electromagnetic interference (EMI) shielding structure.

Aspects of the present disclosure also provide a method of manufacturing a semiconductor package having an effective EMI shielding structure.

However, aspects of the present disclosure are not limited to those set forth herein. The above and other aspects of the present disclosure will become more apparent to one of ordinary skill in the art to which the present disclosure pertains by referencing the detailed description of the present disclosure provided below.

According to aspects of the present disclosure, a semiconductor package includes a first semiconductor chip including a first surface on which a first connection pad is disposed, and a second surface opposite the first surface in a first direction, a second semiconductor chip on the second surface and including a third surface on which a second connection pad is disposed, and a fourth surface opposite the third surface in the first direction, and a connection structure on the first surface of the first semiconductor chip, The connection structure includes a redistribution layer connected to the first connection pad and the second connection pad, a fifth surface facing the first surface, a sixth surface opposite the fifth surface in the first direction, and a grounding pad, a first connecting wire connecting the first connection pad and the redistribution layer and extending in the first direction, a second connecting wire connecting the second connection pad and the redistribution layer and extending in the first direction, a shielding plate on the fourth surface of the second semiconductor chip, and a shielding wire connecting the shielding plate and the grounding pad and extending lengthwise in the first direction.

According to further aspects of the present disclosure, a semiconductor package includes a first semiconductor chip including a first surface on which a first connection pad is disposed, and a second surface opposite the first surface in a first direction, a second semiconductor chip including a third surface facing the second surface of the first semiconductor chip, and a fourth surface opposite the second surface in the first direction, the third surface including a first area at least partially overlapping with the first semiconductor chip in the first direction and a second area free from the first semiconductor chip, and a second connection pad disposed on the third surface in the second area, a connection structure including a fifth surface facing the first surface of the first semiconductor chip, a sixth surface opposite the fifth surface, and a plurality of grounding pads on the fifth surface, a first connecting wire between the first semiconductor chip and the connection structure, and contacting the first connection pad and the connection structure, a second connecting wire between the second semiconductor chip and the connection structure, and contacting the second connection pad and the connection structure, a shielding plate on the fourth surface of the second semiconductor chip, and a plurality of shielding wires between the shielding plate and the connection structure, the plurality of shielding wires at least partially surrounding the first semiconductor chip and second semiconductor chip, and each shielding wire including a first end connected to the shielding plate and a second end connected to a respective ground pad of the plurality of grounding pads.

According to further aspects of the present disclosure, a method of manufacturing a semiconductor package includes providing a carrier, attaching a molding film to the carrier, positioning a shielding plate on the molding film, disposing a first semiconductor chip, which includes a first surface on which a first connection pad is disposed and a second surface opposite the first surface in a first direction, on the shielding plate such that the second surface of the first semiconductor chip faces the shielding plate, disposing a second semiconductor chip, which includes a third surface on which a second connection pad is disposed and a fourth surface opposite the third surface in the first direction, on the first semiconductor chip such that the fourth surface of the second semiconductor chip faces the first semiconductor chip, connecting a first connecting wire, which extends in the first direction, to the first connection pad, connecting a second connecting wire, which extends in the first direction, to the second connection pad, connecting a shielding wire, which extends in the first direction, to the shielding plate, and positioning a connection structure, which includes a redistribution layer connected to the first connection pad through the first connecting wire and the second connection pad through the second connecting wire, and a grounding pad connected to the shielding plate through the shielding wire, on the second semiconductor chip.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 through FIG. 4 illustrate a semiconductor package according to embodiments of the present disclosure.

FIG. 5 is a flowchart illustrating an example method of manufacturing a semiconductor package according to embodiments of the present disclosure.

FIG. 6 through FIG. 15 illustrate example intermediate stages of the method of manufacturing a semiconductor package according to embodiments of the present disclosure.

FIG. 16 and FIG. 17 illustrate example steps of manufacturing a semiconductor package according to embodiments of the present disclosure.

FIG. 18 is a block diagram illustrating an example configuration of a semiconductor package according to embodiments of the present disclosure.

FIG. 19 is a block diagram illustrating an example configuration of a semiconductor package according to embodiments of the present disclosure.

### DETAILED DESCRIPTION

Advantages and features of the present disclosure, and a method of achieving the advantages and features will become apparent with reference to embodiments described below in detail together with the accompanying drawings. However, embodiments of the present disclosure are not limited to the embodiments as disclosed herein, but may be implemented in various different forms. Thus, these embodiments are set forth only to make the present disclosure, and to inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

It will also be understood that when a first element or layer is referred to as being present “on” a second element or layer, the first element may be disposed directly on the second element or may be disposed indirectly on the second element with a third element or layer being disposed between the first and second elements or layers. It will also be understood that when a first element or layer is referred to as being present “under” a second element or layer, the first element may be disposed directly under the second element or may be disposed indirectly under the second element with a third element or layer being disposed between the first and second elements or layers. It will be understood that when an element or layer is referred to as being “connected to”, or “coupled to” another element or layer, it may be directly connected to or coupled to another element or layer, or one or more intervening elements or layers therebetween may be present. In addition, it will also be understood that when an element or layer is referred to as being “between” two elements or layers, it may be the only element or layer between the two elements or layers, or one or more intervening elements or layers therebetween may also be present.

In addition, it will also be understood that when an element or layer is referred to as being “between” two elements or layers, it may be the only element or layer between the two elements or layers, or one or more intervening elements or layers therebetween may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

Spatially relative terms, such as “beneath,” “below,” “lower,” “under,” “above,” “upper,” and the like, may be used herein for ease of illustration to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

The term “upper part” (or “upper surface”) may be defined based on a first direction D1, and the term “lower part” (or “lower surface”) may be defined based on the opposite direction of the first direction D1.

As used herein, “embodiments”, “examples”, “aspects”, and the like should not be construed such that any aspect or design as described is superior to or advantageous over other aspects or designs.

Further, the term “or” means “inclusive or” rather than “exclusive or”. That is, unless otherwise stated or clear from the context, the expression that “x uses a or b” means any one of natural inclusive permutations.

As used herein, an element or region that is “covering” or “surrounding” or “filling” another element or region may completely or partially cover or surround or fill the other element or region.

The term “exposed” (or “expose,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments of the present disclosure will now be described with reference to the attached drawings

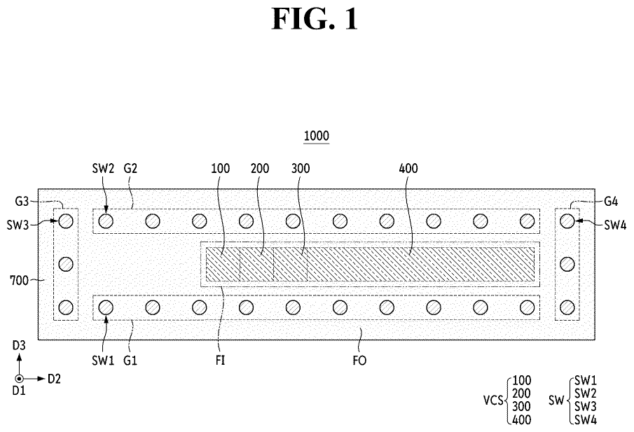

FIG. 1 through FIG. 4 illustrate a semiconductor package 1000 according to embodiments of the present disclosure.

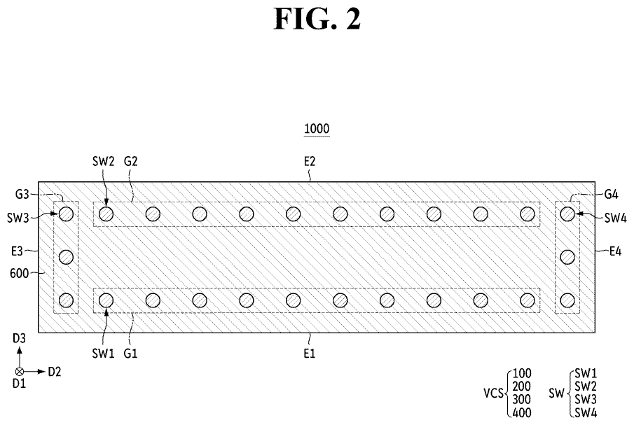

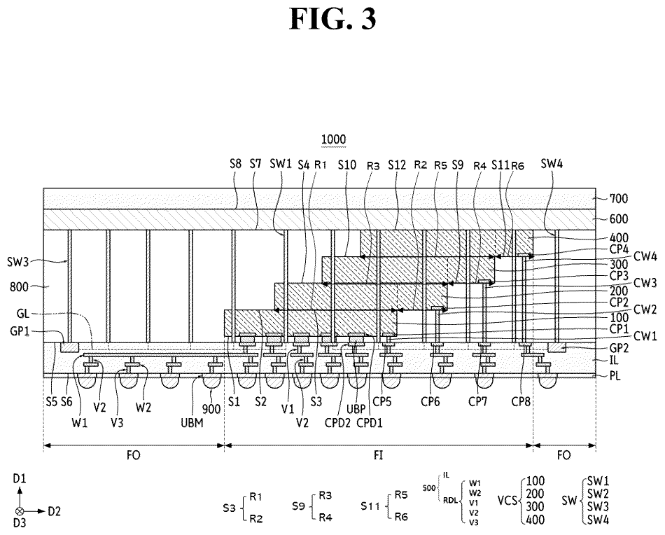

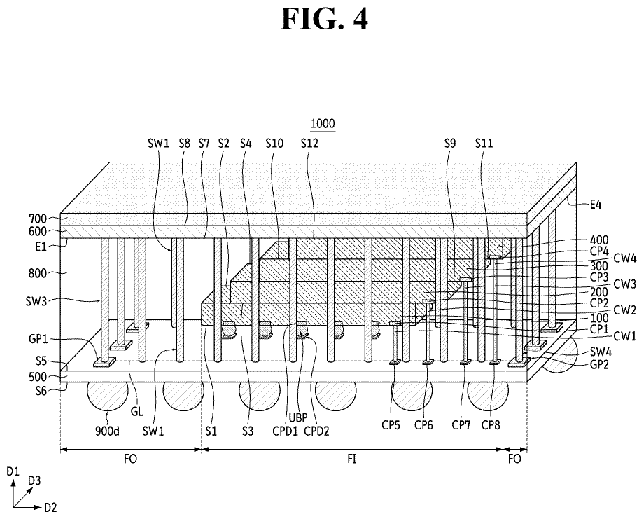

FIG. 1 and FIG. 2 are plan views illustrating part of the semiconductor package 1000 according to embodiments of the present disclosure, FIG. 3 is a front view of the semiconductor package 1000, and FIG. 4 is a perspective view of the semiconductor package 1000. The semiconductor package 1000 will hereinafter be described with reference to FIG. 1 through FIG. 4.

As shown in FIGS. 1-4, according to embodiments of the present disclosure, the semiconductor package 1000 may include a stacked chip structure VCS, which includes a plurality of first, second, third, and fourth semiconductor chips 100, 200, 300, and 400, a connection structure 500, first, second, third, and fourth connecting wires CW1, CW2, CW3, and CW4, a shielding plate 600, shielding wires SW, bumps UBP, and connection terminals 900.

In some embodiments, the semiconductor package 1000 may be a stacked fan-out wafer-level semiconductor package. In some embodiments, the semiconductor package 1000 may include a plurality of first, second, third, and fourth semiconductor chips 100, 200, 300, and 400 that are sequentially stacked in the opposite direction of the first direction D1. In some embodiments, the first, second, third, and fourth semiconductor chips 100, 200, 300, and 400 may be stacked in a stair-like structure on the shielding plate 600.

For example, the fourth semiconductor chip 400 may be stacked first on the shielding plate 600. As shown in FIG. 3, in some embodiments, the fourth semiconductor chip 400 may include an eleventh surface S11 and a twelfth surface S12 that are opposite to each other in the first direction D1. In some embodiments, the fourth semiconductor chip 400 may be disposed on the shielding plate 600 such that the twelfth surface S12 may face the shielding plate 600.

Thereafter, the third semiconductor chip 300 may be stacked on the fourth semiconductor chip 400. The third semiconductor chip 300 may include a ninth surface S9 and a tenth surface S10 that are opposite to each other in the first direction D1. The third semiconductor chip 300 may be stacked on the fourth semiconductor chip 400 such that the tenth surface S10 may face the eleventh surface S11 of the fourth semiconductor chip 400. The third semiconductor chip 300 may be disposed to protrude further in the opposite direction of a second direction D2 compared to the fourth semiconductor chip 400.

The ninth surface S9 of the third semiconductor chip 300 may include a third area R3 and a fourth area R4. The third area R3 may be an area at least partially overlapping with the second semiconductor chip 200 in the first direction D1, and the fourth area R4 may be an area exposed by the second semiconductor chip 200 (i.e., the fourth area R4 may be an area free from the second semiconductor chip 200 in the first direction D1).

The eleventh surface S11 of the fourth semiconductor chip 400 may include a fifth area R5 and a sixth area R6. The fifth area R5 may be an area at least partially overlapping with the third semiconductor chip 300 in the first direction D1, and the sixth area R6 may be an area exposed by the third semiconductor chip 300 (i.e., the sixth area R6 may be an area free from the third semiconductor chip 300 in the first direction D1).

Thereafter, the second semiconductor chip 200 may be stacked on the third semiconductor chip 300. The second semiconductor chip 200 may include a third surface S3 and a fourth surface S4 that are opposite to each other in the first direction D1. The second semiconductor chip 200 may be stacked on the third semiconductor chip 300 such that the fourth surface S4 may face the ninth surface S9 of the third semiconductor chip 300. The second semiconductor chip 200 may be disposed to protrude further in the opposite direction of the second direction D2 compared to the third semiconductor chip 300.

The third surface S3 of the second semiconductor chip 200 may include a first area R1 and a second area R2. The first area R1 may be an area at least partially overlapping with the first semiconductor chip 100 in the first direction D1, and the second area R2 may be an area exposed by the first semiconductor chip 100 (i.e., the second area R2 may be an area free from the first semiconductor chip 100 in the first direction D1).

The first semiconductor chip 100 may include a first surface S1 and a second surface S2 that are opposite to each other in the first direction D1, and the first semiconductor chip 100 may be stacked on the second semiconductor chip 200 such that the second surface S2 may face the third surface S3 of the second semiconductor chip 200. When the first semiconductor chip 100 is stacked on the second semiconductor chip 200, the first semiconductor chip 100 may be disposed to protrude further in the opposite direction of the second direction D2 compared to the second semiconductor chip 200.

The first surface S1 of the first semiconductor chip 100 may include a first connection pad CP1 and first chip pads CPD1. The first connection pad CP1 may be disposed adjacent an edge of the first surface S1. In some embodiments, a second connection pad CP2 may be disposed in the second area R2 of the third surface S3 of the second semiconductor chip, which is part of the third surface S3 that is not overlapped by the first semiconductor chip 100 in the first direction D1 and is exposed by the first semiconductor chip 100 (i.e., the second area R2 is an area free from the first semiconductor chip 100 in the first direction D1). A plurality of first chip pads CPD1 may be formed in a generally central part and/or adjacent an edge part of the first surface S1. The first chip pads CPD1 of the first semiconductor chip 100 may be rewired by the connection structure 500 and connected to the connection terminals 900 disposed in a fan-out area FO.

The first, second, third, and fourth semiconductor chips 100, 200, 300, and 400 may be stacked and attached to one another through adhesive layers disposed in between the semiconductor chips 100, 200, 300, and 400. The adhesive layers may be formed of a material such as non-conductive film (NCF), anisotropic conductive film (ACF), ultraviolet (UV) film, instant adhesive, thermosetting adhesive, laser curable adhesive, ultrasonic curable adhesive, or non-conductive paste (NCP).

The first, second, third, and fourth semiconductor chips 100, 200, 300, and 400 may be volatile memory chips, such as dynamic random-access memories (DRAMs), but the present disclosure is not limited thereto. Alternatively, at least one of the first, second, third, and fourth semiconductor chips 100, 200, 300, and 400 may be a logic chip or a non-volatile memory chip.

FIG. 1 through FIG. 4 illustrate that four semiconductor chips 100, 200, 300, 400 are included in the stacked chip structure VCS of the semiconductor package 1000, but the present disclosure is not limited thereto. That is, the number of semiconductor chips included in the semiconductor package 1000 may be less than or greater than four. For convenience, the following description will primarily focus on an embodiment where the semiconductor package 1000 includes four semiconductor chips, i.e., the first, second, third, and fourth semiconductor chips 100, 200, 300, and 400.

In some embodiments, the connection structure 500 may include a fan-in area FI and the fan-out area FO. The fan-out area FO may be disposed to at least partially surround the fan-in area FI. The first, second, third, and fourth semiconductor chips 100, 200, 300, and 400 may be disposed in the fan-in area FI. The fan-out area FO may include configurations for rewiring the first, second, third, and fourth connection pads CP1, CP2, CP3, and CP4 of the first through fourth semiconductor chips 100, 200, 300, and 400 to the outside of the first through fourth semiconductor chips 100, 200, 300, and 400 (e.g., to the external environment of the semiconductor package 1000).

In some embodiments, the connection structure 500 may include an insulating layer IL, first and second wiring layers W1 and W2, first vias V1, second vias V2, and third vias V3. The connection structure 500 may have a fifth surface S5 and a sixth surface S6 that are opposite to each other in the first direction D1. The connection structure 500 may be disposed such that the fifth surface S5 may face the first surface S1 of the first semiconductor chip 100. The connection structure 500 may be formed to rewire the first chip pads CPD1 and the first, second, third, and fourth connection pads CP1, CP2, CP3, and CP4.

In some embodiments, the connection structure 500 may include first grounding pads GP1, second grounding pads GP2, second chip pads CPD2, and fifth, sixth, seventh, and eighth connection pads CP5, CP6, CP7, and CP8, which are all disposed on the fifth surface S5. The first grounding pads GP1 and the second grounding pads GP2 may be patterned on the fifth surface S5 of the connection structure 500. The first grounding pads GP1 and the second grounding pads GP2 may be formed on the connection structure 500 such that their top surfaces may be at least partially exposed without protruding from the fifth surface S5. In this case, the first grounding pads GP1 and the second grounding pads GP2 may be integrally formed with the grounding layer within the connection structure 500. The first grounding pads GP1 and the second grounding pads GP2 may be patterned adjacent the outer edges of the fifth surface S5 of the connection structure 500 extending in the third direction D3. The first grounding pads GP1 and the second grounding pads GP2 may be formed in solid lines or hidden lines. The first grounding pads GP1 and the second grounding pads GP2 may be connected to grounding lines GL patterned within the insulating layer IL.

Referring to FIG. 4, the first grounding pads GP1 may be arranged in a row adjacent an outer edge of the connection structure 500 and extending in the third direction D3, and the second grounding pads GP2 may be arranged in a row adjacent the opposing outer edge of the connection structure 500 and extending in the third direction D3.

In some embodiments, the bumps UBP may be disposed between the first surface S1 of the first semiconductor 100 and the fifth surface S5 of the connection structure 500. A first (e.g., upper) surface of the bumps UBP may contact the first chip pads CPD1, and a second opposing (e.g., lower) surface of the bumps UBP may contact the second chip pads CPD2. The bumps UBP may physically support the first semiconductor chip 100 and electrically connect the first semiconductor chip 100 to the connection structure 500.

The insulating layer IL may include an insulating material such as a photo-imageable dielectric (PID). The first wiring layer W1, the second wiring layer W2, the first vias V1, the second vias V2, and the third vias V3 may be patterned within the insulating layer IL. The first wiring layer W1, the second wiring layer W2, the first vias V1, the second vias V2, and the third vias V3 may form a redistribution layer RDL. The first and second wiring layers W1 and W2 may extend in the second direction D2, and the first wiring layer W1, the second wiring layer W2, the first vias V1, the second vias V2, and the third vias V3 may extend in the first direction D1. The first vias V1 may connect the second chip pads CPD2 to the first wiring layer W1. The second vias V2 may connect the first wiring layer W1 to the second wiring layer W2. The third vias V3 may connect the second wiring layer W2 to under-bump metallizations UBM.

However, the configuration of the connection structure 500 is not limited to what has been described above. Alternatively, for example, the insulating layer IL of the connection structure 500 may be multi-layered, and the first and second wiring layers W1 and W2 may also be multi-layered. In this case, the first vias V1, the second vias V2, and the third vias V3 may also be multi-layered to electrically connect wiring layers from different layers.

In some embodiments, a passivation layer PL may be disposed on the sixth surface S6 of the connection structure 500. The passivation layer PL may protect the connection structure 500 from potential external physical and/or chemical damage. The passivation layer PL may include openings that expose at least portions of the redistribution layer RDL of the connection structure 500. Tens to thousands of openings may be formed in the passivation layer PL. The passivation layer PL may include an insulating resin and inorganic filler. A surface treatment layer such as nickel (Ni)/gold (Au) may be formed on the exposed surface of the redistribution layer RDL.

The under-bump metallizations UBM may be connected to the redistribution layer RDL of the connection structure 500 and exposed through the openings in the passivation layer PL. The under-bump metallizations UBM may be formed in the openings of the passivation layer PL using a metallization method with a metallic material.

The connection terminals 900 may be attached to a surface of the under-bump metallizations UBM. The connection terminals 900 may physically and/or electrically connect the semiconductor package 1000 to the external environment. For example, the semiconductor package 1000 may be mounted on the main board of an electronic device through the connection terminals 900. The connection terminals 900 may be formed of a low-melting-point metal, such as tin (Sn) or an alloy thereof. For example, the connection terminals 900 may be formed using solder, but the present disclosure is not limited thereto. The connection terminals 900 may be in the form of lands, balls, pins, or other shapes. The connection terminals 900 may be formed as multi-layers or single layers. If formed as multi-layers, the connection terminals 900 may include copper pillars and solder. Alternatively, if formed as single layers, the connection terminals 900 may include tin (Sn)-silver (Ag) solder or copper (Cu). Tens to thousands of connection terminals 900 may be formed depending on the number of under-bump metallizations UBM, but the present disclosure is not limited thereto.

In some embodiments, the second connection pad CP2 may be disposed on the third surface S3 of the second semiconductor chip 200, particularly, adjacent an edge of the third surface S3. The third connection pad CP3 may be disposed on the ninth surface S9 of the third semiconductor chip 300, particularly, adjacent an edge of the ninth surface S9. For example, the third connection pad CP3 may be located in the fourth area R4 of the ninth surface S9 of the third semiconductor chip 300, which is exposed by (i.e., free from) the second semiconductor chip 200 and does not overlap with the second semiconductor chip 200 in the first direction D1. The fourth connection pad CP4 may be disposed on the eleventh surface S11 of the fourth semiconductor chip 400, particularly, adjacent an edge of the eleventh surface S11. For example, the fourth connection pad CP4 may be located in the sixth area R6 of the eleventh surface S11 of the fourth semiconductor chip 400, which is exposed by (i.e., free from) the third semiconductor chip 300 and does not overlap with the third semiconductor chip 300 in the first direction D1.

The first connecting wire CW1 may extend lengthwise in the first direction D1. The first connecting wire CW1 may extend lengthwise in a direction perpendicular to the first and fifth surfaces S1 and S5 of the first semiconductor chip 100 and connection structure 500, respectively. The first connecting wire CW1 may connect the first and fifth connection pads CP1 and CP5. A first end of the first connecting wire CW1 may contact a surface (e.g., lower surface) of the first connection pad CP1, and a second end of the first connecting wire CW1 may contact a surface (e.g., upper surface) of the fifth connection pad CP5. The fifth connection pad CP5 may be electrically connected to the connection terminals 900 through the redistribution layer RDL patterned in the insulating layer IL, including the first vias V1, the first wiring layer W1, the second vias V2, the second wiring layer W2, and the third via V3. That is, the first connecting wire CW1 may be configured to physically and electrically connect the first semiconductor chip 100 to the outside of the semiconductor package 1000.

The second connecting wire CW2 may extend lengthwise in the first direction D1. The second connecting wire CW2 may extend lengthwise in a direction perpendicular to the third and fifth surfaces S3 and S5 of the second semiconductor chip 300 and connection structure 500, respectively. The second connecting wire CW2 may connect the second and sixth connection pads CP2 and CP6. A first end of the second connecting wire CW2 may contact the bottom surface of the second connection pad CP2, and a second end of the second connecting wire CW2 may contact the upper surface of the sixth connection pad CP6. The sixth connection pad CP6 may be electrically connected to the connection terminals 900 through the redistribution layer RDL patterned in the insulating layer IL, including the first vias V1, the first wiring layer W1, the second vias V2, the second wiring layer W2, and the third vias V3. That is, the second connecting wire CW2 may be configured to physically and electrically connect the second semiconductor chip 200 to the outside of the semiconductor package 1000 (e.g., to the external environment of the semiconductor package 1000).

The third connecting wire CW3 may extend lengthwise in the first direction D1. The third connecting wire CW3 may extend lengthwise in a direction perpendicular to the fifth and ninth surfaces S5 and S9 of the connection structure 500 and the third semiconductor chip 300, respectively. The third connecting wire CW3 may connect the third and seventh connection pads CP3 and CP7. A first end of the third connecting wire CW3 may contact a surface (e.g., lower surface) of the third connection pad CP3, and a second end of the third connecting wire CW3 may contact a surface (e.g., upper surface) of the seventh connection pad CP7. The seventh connection pad CP7 may be electrically connected to the connection terminals 900 through the redistribution layer RDL patterned in the insulating layer IL, including the first vias V1, the first wiring layer W1, the second vias V2, the second wiring layer W2, and the third vias V3. That is, the third connecting wire CW3 may be configured to physically and electrically connect the third semiconductor chip 300 to the outside of the semiconductor package 1000 (e.g., to the external environment of the semiconductor package 1000).

The fourth connecting wire CW4 may extend lengthwise in the first direction D1. The fourth connecting wire CW4 may extend lengthwise in a direction perpendicular to the fifth and eleventh surfaces S5 and S11 of the connection structure 500 and the fourth semiconductor ship 400, respectively. The fourth connecting wire CW4 may connect the fourth and eighth connection pads CP4 and CP8. A first end of the fourth connecting wire CW4 may contact a surface (e.g., lower surface) of the fourth connection pad CP4, and a second end of the fourth connecting wire CW4 may contact a surface (e.g., upper surface) of the eighth connection pad CP8. The eighth connection pad CP8 may be electrically connected to the connection terminals 900 through the redistribution layer RDL patterned in the insulating layer IL, including the first vias V1, the first wiring layer W1, the second vias V2, the second wiring layer W2, and the third vias V3. That is, the fourth connecting wire CW4 may be configured to physically and electrically connect the fourth semiconductor chip 400 to the outside of the semiconductor package 1000.

The shielding plate 600 may be disposed on the fourth semiconductor chip 400. The shielding plate 600 may include a seventh surface S7 and an eighth surface S8 that are opposite to each other in the first direction D1. The seventh surface S7 of the shielding plate 600 may face the twelfth surface S12 of the fourth semiconductor chip 400, and the eighth surface S8 of the shielding plate 600 may be opposite to the twelfth surface S12 of the fourth semiconductor chip 400. The shielding plate 600 may include a metal material. The shielding plate 600 may have a rectangular plate shape.

Referring to FIG. 2, the shielding plate 600 may include first, second, third, and fourth edges E1, E2, E3, and E4. The first and second edges E1 and E2 may extend in a second direction D2 and may be spaced apart from each other in a third direction D3. The third and fourth edges E3 and E4 may extend in the third direction D3 and may be spaced apart in the second direction D2. A plurality of shielding wires SW (e.g., SW1, SW2, SW3, SW4), which extend lengthwise in the first direction D1, may be disposed on the seventh surface S7 of the shielding plate 600.

The shielding wires SW may be disposed between the shielding plate 600 and the connection structure 500, perpendicular to the seventh surface S7 of the shielding plate 600 and the fifth surface S5 of the connection structure 500. The shielding wires SW may be placed in the fan-out area FO, at least partially surrounding the stacked chip structure VCS. Referring to FIG. 2, the shielding wires SW may be divided into first, second, third, and fourth groups G1, G2, G3, and G4. The first group G1 may include first shielding wires SW1, the second group G2 may include second shielding wires SW2, the third group G3 may include third shielding wires SW3, and the fourth group G4 may include fourth shielding wires SW4.

The first group G1 may be disposed to correspond to the first edge E1 of the shielding plate 600, the second group G2 to the second edge E2 of the shielding plate 600, the third group G3 to the third edge E3 of the shielding plate 600, and the fourth group G4 to the fourth edge E4 of the shielding plate 600. The first shielding wires SW1 in the first group G1 may be spaced apart from one another adjacent the first edge E1 of the shielding plate 600 in the second direction D2. The second shielding wires SW2 in the second group G2 may be spaced apart from one another adjacent the second edge E2 of the shielding plate 600 in the second direction D2. The third shielding wires SW3 in the third group G3 may be spaced apart from one another adjacent the third edge E3 of the shielding plate 600 in the third direction D3. The fourth shielding wires SW4 in the fourth group G4 may be spaced apart from one another adjacent the fourth edge E4 of the shielding plate 600 in the third direction D3.

A first end of each of the shielding wires SW may be connected to the shielding plate 600, and a second end of each of the shielding wires SW may be connected to either the first grounding pads GP1 or the second grounding pads GP2. For example, referring to FIG. 3 and FIG. 4, the second ends of the first shielding wires SW1 may be electrically connected to the first grounding pads GP1 or the second grounding pads GP2 through grounding lines GL. Similarly, the second ends of the second shielding wires SW2 may be electrically connected to the first grounding pads GP1 or the second grounding pads GP2 through the grounding lines GL. The second ends of the third shielding wires SW3 may be grounded to the first grounding pads GP1, and the second ends of the fourth shielding wires SW4 may be grounded to the second grounding pads GP2.

The shielding wires SW may extend lengthwise in the first direction D1. The shielding wires SW may extend in a direction perpendicular to the fifth surface S5 of the connection structure 500 and the seventh surface S7 of the shielding plate 600.

The shielding plate 600 and the shielding wires SW may be configured to electrically shield the semiconductor package 1000, which is a stacked fan-out wafer level package. In the semiconductor package 1000, the shielding plate 600 and the connection structure 500 may be spaced apart from each other in the first direction D1 with the stacked chip structure VCS residing in between. The shielding wires SW may electrically connect the shielding plate 600 to the first grounding pads GP1 and the second grounding pads GP2, formed on the connection structure 500, thereby forming an electromagnetic interference (EMI) shielding structure.

In some embodiments, the semiconductor package 1000 may further include a molding film 700 and a molding layer 800. The molding film 700 may be disposed on the eighth surface S8 of the shielding plate 600. The molding layer 800 may be formed to fill a space between the connection structure 500 and the shielding plate 600. The molding layer 800 may at least partially cover the fifth surface S5 of the connection structure 500, the shielding wires SW, the first, second, third, and fourth connecting wires CW1, CW2, CW3, and CW4, the stacked chip structure VCS, and the seventh surface S7 of the shielding plate 600.

In some embodiments, the molding film 700 may encapsulate and seal the eighth surface S8 of the shielding plate 600, and the molding layer 800 may encapsulate and seal the stacked chip structure VCS. The molding film 700 and the molding layer 800 may include an insulating material, such as an inorganic filler and insulating resin. For example, a thermosetting resin such as an epoxy resin, a thermoplastic resin such as polyimide, or a resin containing a reinforcing material (e.g., an inorganic filler), specifically ABF, FR-4, BT resin, etc., may be sed as the insulating material. Additionally, a molding material such as Epoxy Molding Compound (EMC) may be used. If necessary, a photosensitive material such as a Photo Imageable Encapsulant (PIE) may also be used. An insulating resin such as a thermosetting or thermoplastic resin impregnated with an inorganic filler and/or reinforcing material like glass fiber (e.g., glass cloth or glass fabric) may also be used if needed.

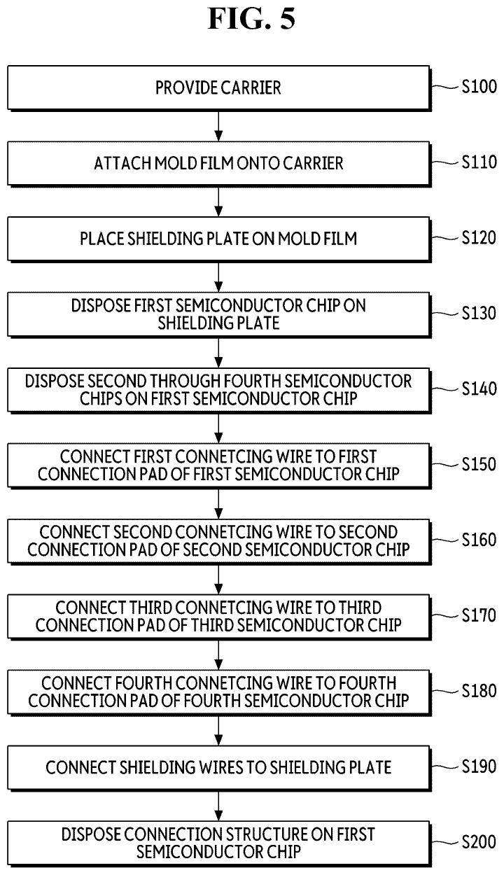

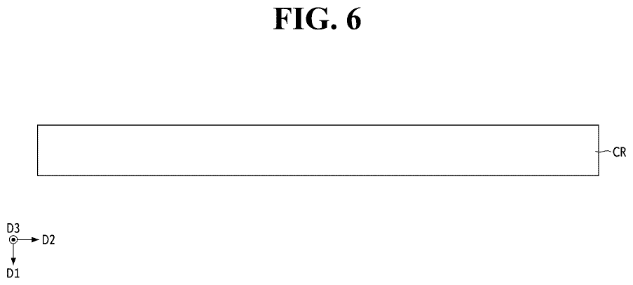

FIG. 5 is a flowchart illustrating an example method of manufacturing a semiconductor package according to embodiments of the present disclosure. FIG. 6 through FIG. 15 illustrate example intermediate stages of the method of manufacturing a semiconductor package according to embodiments of the present disclosure. The method of manufacturing a semiconductor package according to embodiment of the present disclosure will hereinafter be described with reference to FIG. 5 through FIG. 15.

First, referring to FIG. 5 and FIG. 6, in some embodiments, a carrier CR may be provided (S100). On the carrier CR, a stacked chip structure (“VCS” in FIG. 1) may be disposed at the wafer level. The carrier CR may be formed of a material such as a silicon (Si), germanium (Ge), silicon-germanium (SiGe), gallium arsenide (GaAs), metal, glass, plastic, or ceramic substrate, but the present disclosure is not limited thereto. In some embodiments, the carrier CR may be in the form of a wafer.

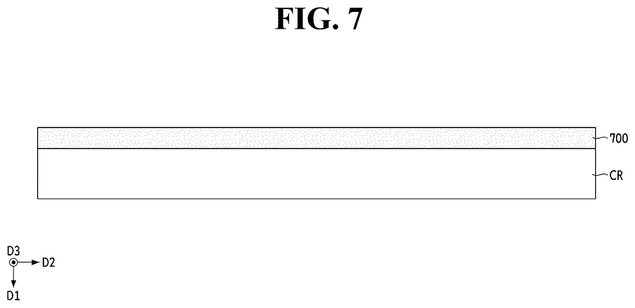

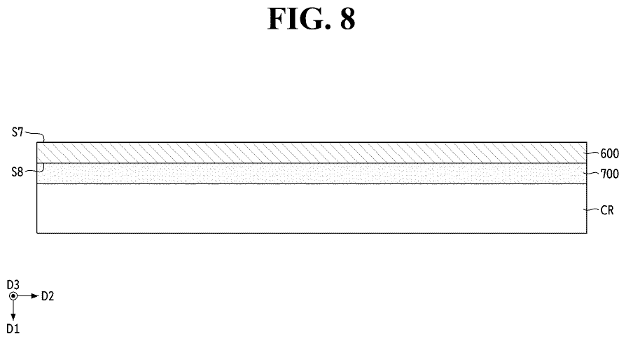

Thereafter, referring to FIG. 5 and FIG. 7, in some embodiments, a molding film 700 may be attached onto the carrier CR (S110). Then, referring to FIG. 5 and FIG. 8, in some embodiments, a shielding plate 600 may be disposed on the molding film 700 (S120). The shielding plate 600 may be disposed on the mold film 700 such that an eighth surface S8 of the shielding plate 600 may face the molding film 700, and a seventh surface S7 of the shielding plate 600 may be opposite to the molding film 700.

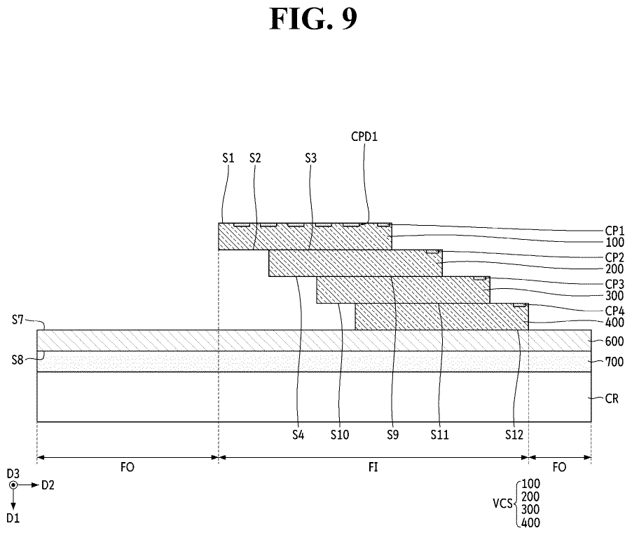

Thereafter, referring to FIG. 5 and FIG. 9, in some embodiments, a fourth semiconductor chip 400 may be disposed on the seventh surface S7 of the shielding plate 600 (S130). The fourth semiconductor chip 400 may be disposed on the shielding plate 600 such that a twelfth surface S12 of the fourth semiconductor chip 400 may face the seventh surface S7 of the shielding plate 600. Thereafter, in some embodiments, a third semiconductor chip 300, a second semiconductor chip 200, and a first semiconductor chip 100 may be sequentially disposed on the fourth semiconductor chip 400. Thus, the fourth semiconductor chip 400, the third semiconductor chip 300, the second semiconductor chip 200, and the first semiconductor chip 100 may be sequentially stacked on the shielding plate 600, forming a stair-like structure on the shielding plate 600.

When the third semiconductor chip 300 is stacked on the fourth semiconductor chip 400, the third semiconductor chip 300 may be disposed to protrude in the opposite direction of a second direction D2 compared to the fourth semiconductor chip 400 such that a third connection pad CP3 formed on the ninth surface S9 of the third semiconductor chip 300 may be exposed to the outside of the stacked chip structure VCS.

Similarly, when the second semiconductor chip 200 and the first semiconductor chip 100 are sequentially stacked on the third semiconductor chip 300, the second semiconductor chip 200 may be disposed to protrude in the opposite direction of the second direction D2 compared to the third semiconductor chip 300 such that a second connection pad CP2 may be exposed to the outside of the stacked chip structure VCS, and the first semiconductor chip 100 may be disposed to protrude in the opposite direction of the second direction D2 compared to the second semiconductor chip 200 such that a first connection pad CP1 may be exposed to the outside of the stacked chip structure VCS.

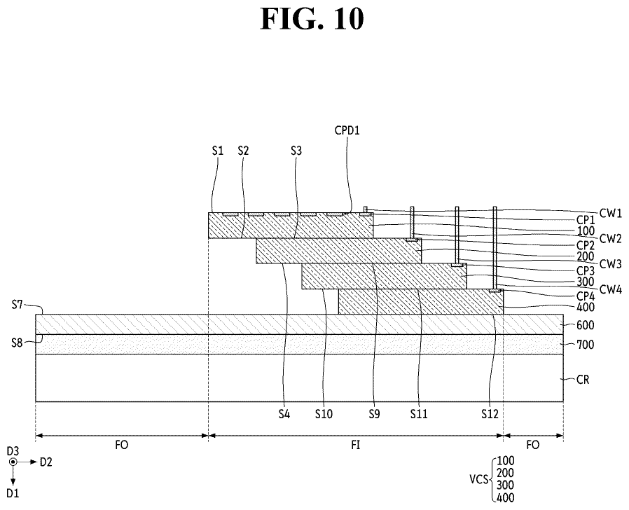

Referring to FIG. 5 and FIG. 10, in some embodiments, first, second, third, and fourth connecting wires CW1, CW2, CW3, and CW4 may be connected to first, second, third, and fourth connection pads CP1, CP2, CP3, and CP4, respectively (S150, S160, S170, and S180). The order in which the first, second, third, and fourth connecting wires CW1, CW2, CW3, and CW4 are connected to the first, second, third, and fourth connection pads CP1, CP2, CP3, and CP4, respectively, is not limited to what is illustrated in FIG. 5.

The first, second, third, and fourth connecting wires CW1, CW2, CW3, and CW4 may extend lengthwise in the first direction D1, and the direction in which the first, second, third, and fourth connecting wires CW1, CW2, CW3, and CW4 extend may be perpendicular to the seventh surface S7 of the shielding plate 600. In some embodiments, the first ends of the first, second, third, and fourth connecting wires CW1, CW2, CW3, and CW4 may contact the first, second, third, and fourth connection pads CP1, CP2, CP3, and CP4, respectively, and the second ends of the first, second, third, and fourth connecting wires CW1, CW2, CW3, and CW4 may face the opposite direction of the first direction D1.

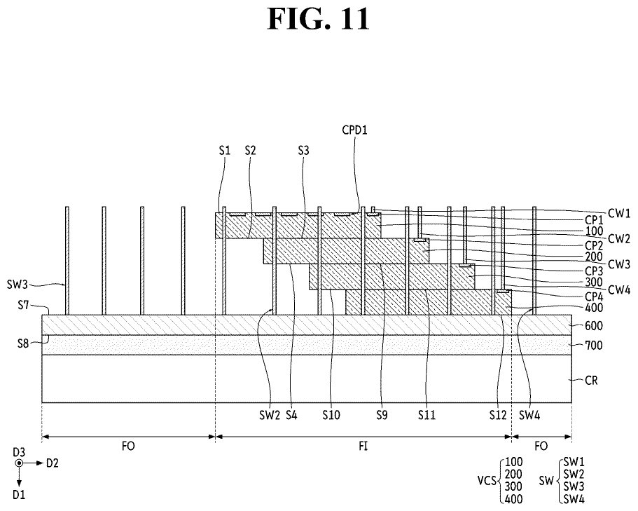

Referring to FIG. 5 and FIG. 11, in some embodiments, shielding wires SW may be connected to the shielding plate 600 (S190). The shielding wires SW may extend lengthwise in the first direction D1, and the direction in which the shielding wires SW extend may be perpendicular to the seventh surface S7 of the shielding plate 600. The first ends of the shielding wires SW may contact the seventh surface S7 of the shielding plate 600, and the shielding wires SW may be electrically connected to the shielding plate 600. The second ends of the shielding wires SW may face the opposite direction of the first direction D1.

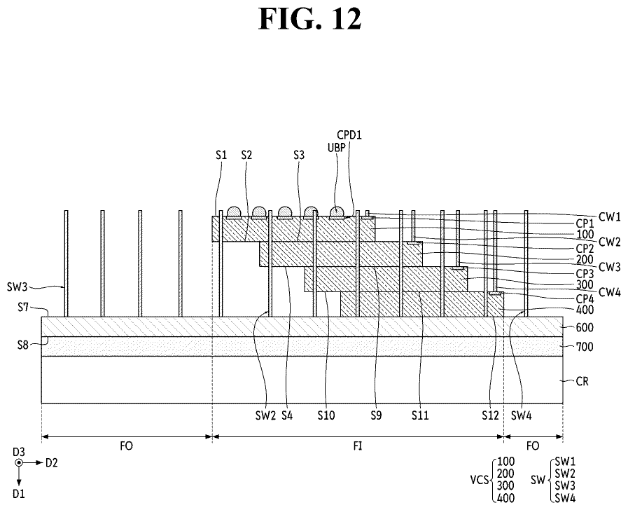

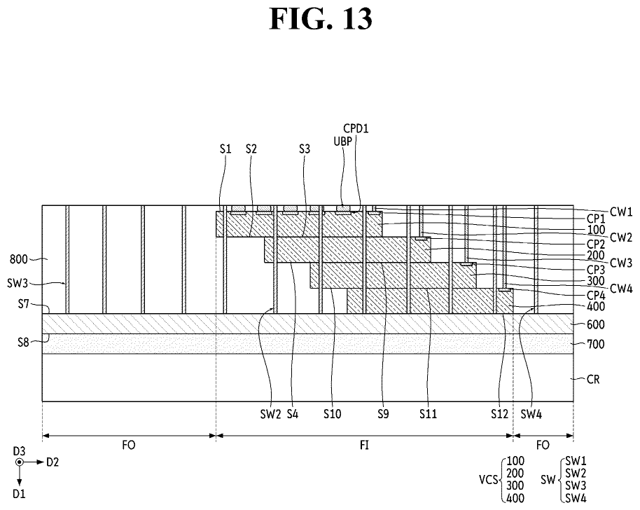

Thereafter, referring to FIG. 12, bumps UBP can be attached to the first chip pads CPD1 arranged on the first surface S1 of the first semiconductor chip 100. Then, referring to FIG. 13, a molding layer 800 can be formed on the seventh surface S7 of the shielding plate 600. In some embodiments, the molding layer 800 may at least partially cover the seventh surface S7 of the shielding plate 600, the shielding wires SW, the first to fourth connecting wires CW1, CW2, CW3, and CW4, the stacked chip structure VCS, and the seventh surface S7 of the shielding plate 600.

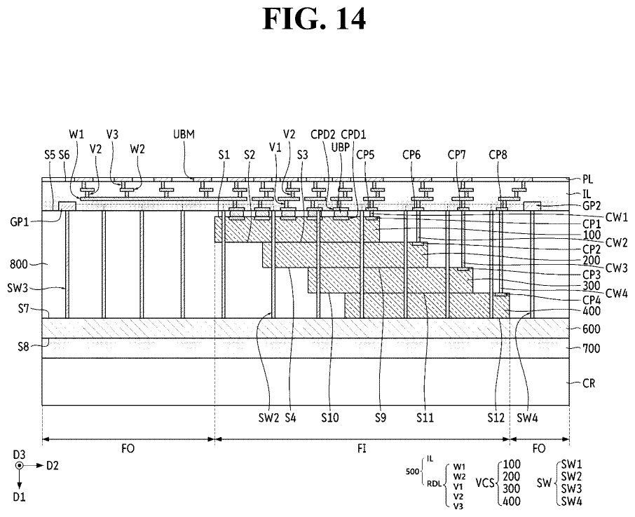

Thereafter, referring to FIG. 5 and FIG. 14, in some embodiments, a connection structure 500 may be disposed on the first semiconductor chip 100 (S200). The connection structure 500 may be disposed on the first semiconductor chip 100 such that first grounding pads GP1 arranged on the fifth surface S5 of the connection structure 500 may be connected to respective third shielding wires SW3 and second grounding pads GP2 may be connected to respective fourth shielding wires SW4. Additionally, in some embodiments, first shielding wires SW1 and second shielding wires SW2 may be connected to grounding lines GL patterned within an insulating layer IL.

Furthermore, in some embodiments, the connection structure 500 may be disposed on the first semiconductor chip 100 such that second chip pads CPD2 arranged on the fifth surface S5 of the connection structure 500 may be connected to the bumps UBP. Also, in some embodiments, the connection structure 500 may be disposed on the first semiconductor chip 100 such that fifth, sixth, seventh, and eighth connection pads CP5, CP6, CP7, and CP8 arranged on the fifth surface S5 of the connection structure 500 may be connected to the first, second, third, and fourth connecting wires CW1, CW2, CW3, and CW4, respectively.

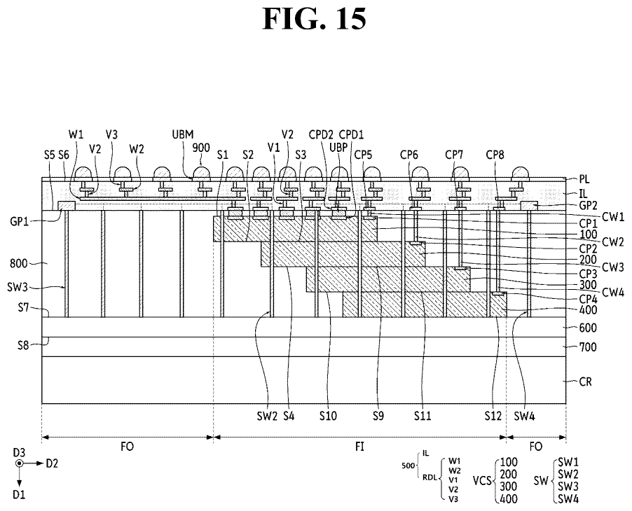

Thereafter, referring to FIG. 15, in some embodiments, connection terminals 900 may be attached to under-bump metallizations UBM formed on the sixth surface S6 of the connection structure 500. Thus, in some embodiments, the first, second, third, and fourth connection pads CP1, CP2, CP3, and CP4 of the first, second, third, and fourth semiconductor chips 100, 200, 300, and 400, arranged in a fan-in area FI, may be rewired by the connection structure 500 and may thus be connected to the connection terminals 900 disposed in a fan-out area FO.

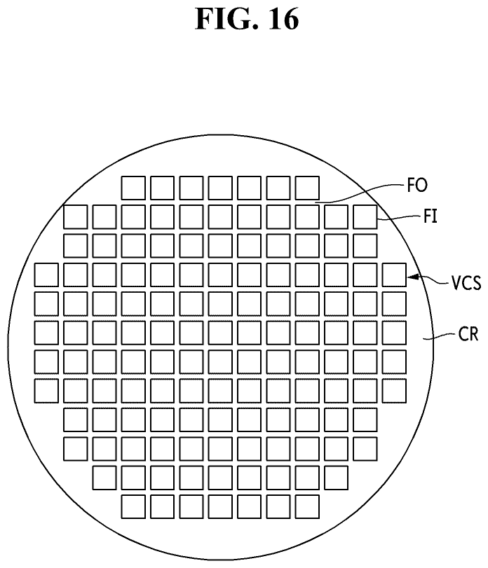

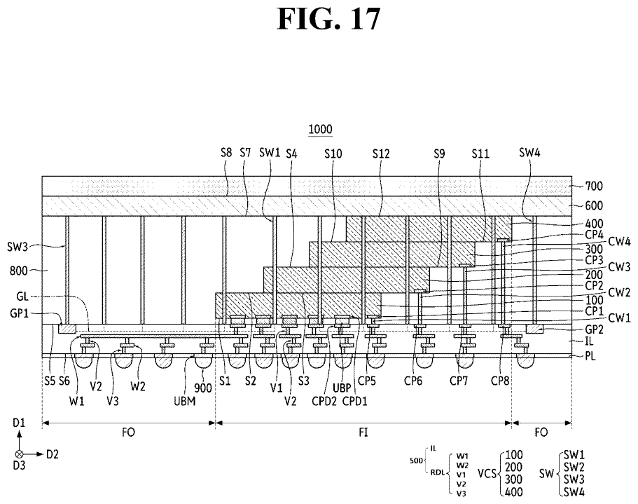

FIG. 16 and FIG. 17 are diagrams illustrating example steps of manufacturing a semiconductor package according to embodiments of the present disclosure.

FIG. 16 is a diagram to help illustrate a method of manufacturing the semiconductor package 100, which is a stacked fan-out wafer level semiconductor package according to embodiments of the present disclosure. A plurality of semiconductor chips (e.g., the stacked chip structure VCS of FIG. 1 through FIG. 4) may be manufactured on silicon (Si), for example, on a Si wafer through a wafer manufacturing process.

Referring to FIG. 16, stacked chip structures (“VCS” in FIG. 1) may be arranged at the wafer level on a carrier CR. The carrier CR may be in the form of a wafer as illustrated in FIG. 16. The areas where the stacked chip structures VCS are arranged on the carrier CR may be fan-in areas FI. The periphery of each of the fan-in areas FI can be defined as a fan-out area FO. That is, the stacked chip structures VCS may be disposed in the fan-in areas FI of the carrier CR, and the area at least partially surrounding the fan-in areas FI may be defined as the fan-out area FO.

FIG. 15 illustrates a single stacked chip structure VCS including the first, second, third, and fourth semiconductor chips 100, 200, 300, and 400 arranged on the carrier CR, but in reality, a plurality of stacked chip structures VCS may be arranged on the carrier CR, as illustrated in FIG. 16. After completing the step of attaching the connection terminals 900, as shown in FIG. 15, the carrier CR may be removed, and the wafer may be separated into individual chips through a singulation process. Through the singulation process, the final manufactured semiconductor package may have the shape of the semiconductor package 1000 illustrated in FIG. 17.

According to the present disclosure, EMI shielding can be achieved by adding the shielding plate 600 and the shielding wires SW during the manufacture of the semiconductor package 1000, where the stacked chip structures VCS are connected to the connection structure 500 through vertical connecting wires (CW1, CW2, CW3, and CW4), without the need for an additional process for providing EMI shielding. As a result, the manufacturing time and costs of the semiconductor package 1000 of the present disclosure can both be reduced.

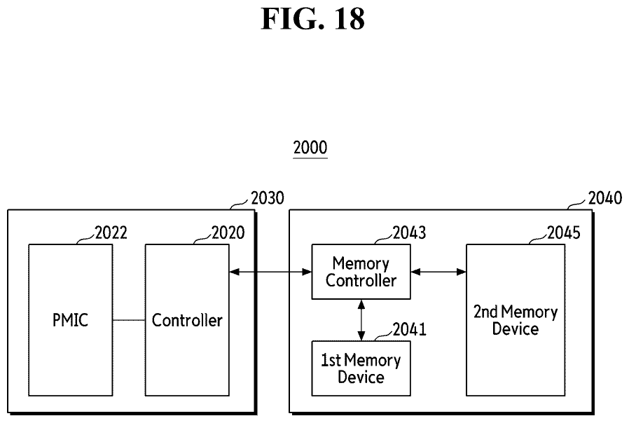

FIG. 18 is a block diagram illustrating an example configuration of a semiconductor package 2000 according to embodiments of the present disclosure.

Referring to FIG. 18, the semiconductor package 2000 may correspond to the semiconductor package 1000 described with reference to FIG. 1 through FIG. 17. In some embodiments, the semiconductor package 2000 may include a first package 2030 and a second package 2040. The first package 2030 may include a controller (e.g., controller chip) 2020, and the second package 2040 may include a first memory device (e.g., memory chip) 2041, a second memory device (e.g., memory chip) 2045, and a memory controller 2043. The first and second memory devices 2041 and 2045 may correspond to semiconductor chips included in a stacked chip structure VCS (e.g., as described herein with reference to FIG. 1 through FIG. 17). The semiconductor package 2000 may further include a power management integrated circuit (PMIC) 2022, which supplies operating voltage currents to the controller chip 2020, the first memory device 2041, the second memory device 2045, and the memory controller 2043, respectively. These operating voltages may be designed to be the same or different.

The semiconductor package 2000 of the present disclosure may be implemented to be included in a personal computer (PC) or a mobile device. The mobile device may be a laptop computer, a mobile phone, a smartphone, a tablet PC, a personal digital assistant (PDA), an enterprise digital assistant (EDA), a digital still camera, a digital video camera, a portable multimedia player (PMP), a personal navigation device (PND), a portable navigation device, a handheld game console, a mobile internet device (MID), a wearable computer, an Internet of Things (IoT) device, an Internet of Everything (IoE) device, or a drone.

The controller 2020 may control the operations of the first memory device 2041, the second memory device 2045, and the memory controller 2043. For example, the controller 2020 may be implemented as an integrated circuit (IC), a system on chip (SoC), an application processor (AP), a mobile AP, a chipset, or a set of chips. The controller 2020 may include a central processing unit (CPU), a graphics processing unit (GPU), and/or a modem. In some embodiments, the controller 2020 may perform the functions of both a modem and an AP.

The memory controller 2043 may control the second memory device 2045 under the control of the controller 2020. The first and second memory devices 2041 and 2045 may be implemented as volatile memory devices. The volatile memory devices may be implemented as random-access memories (RAMs), dynamic RAMs (DRAMs), or static RAMs (SRAMs), but the present disclosure is not limited thereto.

In some embodiments, at least one of the first and second memory devices 2041 and 2045 may be implemented as a storage memory device. The storage memory device may be implemented as a non-volatile memory device. The storage memory device may be implemented as a flash-based memory device, but the present disclosure is not limited thereto. At least one of the first and second memory devices 2041 and 2045 may be implemented as a NAND-type flash memory device. The NAND-type flash memory device may include a two-dimensional (2D) memory cell array or a three-dimensional (3D) memory cell array. The 2D memory cell array or the 3D memory cell array may include a plurality of memory cells, each of which may store one bit of information or two bits or more of information.

When at least one of the first and second memory devices 2041 and 2045 is implemented as a flash-based memory device, the memory controller 2043 may use (or support) a MultiMedia Card (MMC) interface, an embedded MMC (eMMC) interface, or a Universal Flash Storage (UFS) interface, but the present disclosure is not limited thereto.

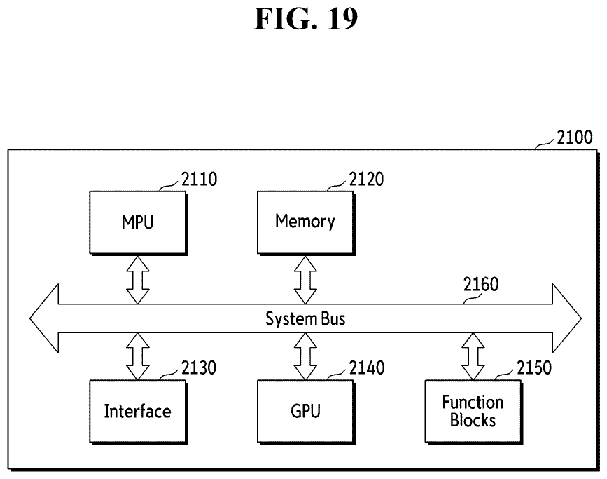

FIG. 19 is a block diagram illustrating an example configuration of a semiconductor package 2100 according to embodiments of the present disclosure.

Referring to FIG. 19, the semiconductor package 2100 may include a micro processing unit (MPU) 2110, a memory 2120, an interface 2130, a GPU 2140, function blocks 2150, and a system bus 2160, which connects the MPU 2110, the memory 2120, the interface 2130, the GPU 2140, and the function blocks 2150. The semiconductor package 2100 may include both the MPU 2110 and the GPU 2140, or only one of the MPU 2110 and the GPU 2140.

The MPU 2110 may include cores and a cache. For example, the MPU 2110 may have multiple cores. The cores of the MPU 2110 may have the same or different performance capabilities. Additionally, the cores of the MPU 2110 may be activated simultaneously or at different times. The memory 2120 may store processing results from the function blocks 2150 under the control of the MPU 2110. For example, the contents stored in the cache of the MPU 2110 may be flushed and stored in the memory 2120. The interface 2130 may handle interactions with external devices. For example, the interface 2130 may perform interfacing with a camera, a liquid crystal display (LCD), and speakers.

The GPU 2140 may perform graphic functions. For example, the GPU 2140 may execute a video codec or process 3D graphics. The function blocks 2150 may perform various functions. For example, if the semiconductor package 2100 is used as an AP in a mobile device, some of the function blocks 2150 may handle a communication function.

The semiconductor package 2100 may correspond to the semiconductor package 1000 described with reference to FIG. 1 through FIG. 17. The MPU 2110 and/or the GPU 2140 may correspond to the first package 2030 described with reference to FIG. 18. The memory 2120 may correspond to the second package 2040 described with reference to FIG. 18. The interface 2130 and the function blocks 2150 may correspond to parts of the first package 2030 described with reference to FIG. 18.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

1. A semiconductor package, comprising:
a first semiconductor chip comprising a first surface on which a first connection pad is disposed, and a second surface opposite the first surface in a first direction;
a second semiconductor chip on the second surface of the first semiconductor chip and comprising a third surface on which a second connection pad is disposed, and a fourth surface opposite the third surface in the first direction;
a connection structure on the first surface of the first semiconductor chip, the connection structure comprising a redistribution layer connected to the first connection pad and the second connection pad, a fifth surface facing the first surface of the first semiconductor chip, a sixth surface opposite the fifth surface in the first direction, and a grounding pad;
a first connecting wire connecting the first connection pad and the redistribution layer and extending in the first direction;
a second connecting wire connecting the second connection pad and the redistribution layer and extending in the first direction;
a shielding plate on the fourth surface of the second semiconductor chip; and
a shielding wire connecting the shielding plate and the grounding pad and extending lengthwise in the first direction.

2. The semiconductor package of claim 1, wherein the first connecting wire extends in a direction perpendicular to the first surface of the first semiconductor chip and the fifth surface of the connection structure.

3. The semiconductor package of claim 1, wherein the second connecting wire extends in a direction perpendicular to the third surface of the second semiconductor chip and the fifth surface of the connection structure.

4. The semiconductor package of claim 1, wherein
the shielding plate includes a seventh surface facing the sixth surface of the connection structure, and an eighth surface opposite the seventh surface in the first direction, and
the shielding wire extends in a direction perpendicular to the fifth surface of the connection structure and the seventh surface of the shielding plate.

5. The semiconductor package of claim 4, further comprising:
a molding layer on the eighth surface of the shielding plate.

6. The semiconductor package of claim 1, further comprising:
a plurality of shielding wires, wherein
the shielding plate includes a first edge and a second edge each extending in a second direction intersecting the first direction, and wherein
the first edge and the second edge are spaced apart from each other in a third direction intersecting the first direction and the second direction.

7. The semiconductor package of claim 6, wherein
the plurality of shielding wires comprises a first group that includes first shielding wires and a second group that includes second shielding wires,
the first shielding wires in the first group are spaced apart from one another adjacent the first edge of the shielding plate in the second direction, and
the second shielding wires in the second group are spaced apart from one another adjacent the second edge of the shielding plate in the second direction.

8. The semiconductor package of claim 7, wherein
the shielding plate further comprises a third edge and a fourth edge each extending in the third direction, and
the third edge and the fourth edge are spaced apart from each other in the second direction.

9. The semiconductor package of claim 8, wherein
the plurality of shielding wires further comprises a third group that includes third shielding wires and a fourth group that includes fourth shielding wires,
the third shielding wires in the third group are spaced apart from one another adjacent the third edge of the shielding plate in the third direction, and
the fourth shielding wires in the fourth group are spaced apart from one another adjacent the fourth edge of the shielding plate in the third direction.

10. The semiconductor package of claim 1, further comprising:
a molding layer in a space between the shielding plate and the connection structure.

11. The semiconductor package of claim 10, wherein the molding layer at least partially covers the first semiconductor chip, the second semiconductor chip, the first connecting wire, the second connecting wire, and a plurality of shielding wires.

12. A semiconductor package, comprising:
a first semiconductor chip comprising a first surface on which a first connection pad is disposed, and a second surface opposite the first surface in a first direction;
a second semiconductor chip comprising a third surface facing the second surface of the first semiconductor chip, and a fourth surface opposite the third surface in the first direction, the third surface comprising a first area at least partially overlapping with the first semiconductor chip in the first direction and a second area free from the first semiconductor chip, and a second connection pad disposed on the third surface in the second area;
a connection structure comprising a fifth surface facing the first surface of the first semiconductor chip, a sixth surface opposite the fifth surface, and a plurality of grounding pads on the fifth surface;
a first connecting wire between the first semiconductor chip and the connection structure, and contacting the first connection pad and the connection structure;
a second connecting wire between the second semiconductor chip and the connection structure, and contacting the second connection pad and the connection structure;
a shielding plate on the fourth surface of the second semiconductor chip; and
a plurality of shielding wires between the shielding plate and the connection structure, the plurality of shielding wires at least partially surrounding the first semiconductor chip and second semiconductor chip, and each shielding wire comprising a first end connected to the shielding plate and a second end connected to a respective ground pad of the plurality of grounding pads.

13. The semiconductor package of claim 12, wherein the first connecting wire, the second connecting wire, and the plurality of shielding wires extend in the first direction.

14. The semiconductor package of claim 12, wherein
the connection structure comprises an insulating layer and a wiring layer residing within the insulating layer and extending in a second direction intersecting the first direction, and
the wiring layer connects the first connecting wire and the second connecting wire.

15. The semiconductor package of claim 14, wherein
the connection structure further comprises a via residing within the insulating layer and extending in the first direction, and a third connection pad on the fifth surface of the connection structure, and
the via connects the wiring layer and the third connection pad.

16. The semiconductor package of claim 12, wherein
the plurality of shielding wires comprises first shielding wires, second shielding wires, third shielding wires, and fourth shielding wires,
the shielding plate comprises a first edge and a second edge each extending in a second direction intersecting the first direction, and a third edge and a fourth edge each extending in a third direction intersecting the first direction and the second direction,
the first shielding wires are spaced apart from one another adjacent the first edge in the second direction,
the second shielding wires are spaced apart from one another adjacent the second edge in the second direction,
the third shielding wires are spaced apart from one another adjacent the third edge in the third direction, and
the fourth shielding wires are spaced apart from one another adjacent the fourth edge in the third direction.

17. The semiconductor package of claim 12, further comprising:
a plurality of bumps between the first surface of the first semiconductor chip and the fifth surface of the connection structure; and
a plurality of connection terminals on the sixth surface of the connection structure.

18. A method of manufacturing a semiconductor package, the method comprising:
providing a carrier;
attaching a molding film to the carrier;
positioning a shielding plate on the molding film;
disposing a first semiconductor chip comprising a first surface on which a first connection pad is disposed and a second surface opposite the first surface in a first direction, on the shielding plate such that the second surface of the first semiconductor chip faces the shielding plate;
disposing a second semiconductor chip comprising a third surface on which a second connection pad is disposed and a fourth surface opposite the third surface in the first direction, on the first semiconductor chip such that the fourth surface of the second semiconductor chip faces the first semiconductor chip;
connecting a first connecting wire, which extends in the first direction, to the first connection pad;
connecting a second connecting wire, which extends in the first direction, to the second connection pad;
connecting a shielding wire, which extends in the first direction, to the shielding plate; and
positioning a connection structure comprising a redistribution layer connected to the first connection pad through the first connecting wire and the second connection pad through the second connecting wire, and a grounding pad connected to the shielding plate through the shielding wire, on the second semiconductor chip.

19. The method of claim 18, further comprising:
forming a molding layer to at least partially cover the first semiconductor chip, the second semiconductor chip, the first connecting wire, the second connecting wire, the shielding wire, and the shielding plate before positioning the connection structure on the second semiconductor chip.

20. The method of claim 18, wherein
the connection structure comprises a fifth surface facing the second semiconductor chip and a sixth surface opposite the fifth surface in the first direction, and
the method further comprises, after positioning the connection structure on the second semiconductor chip, positioning a plurality of connection terminals on the sixth surface of the connection structure.
